(19) United States
(12) Patent Application Publication
(10) Pub. No.: US 2006/0016469 A1
(43) Pub. Date: Jan. 26, 2006

(54) Thermoelectric effect apparatus, energy direct conversion system , and energy conversion system

(75) Inventor: Yoshiomi Kondoh, Gunma (JP)

Correspondence Address: FOLEY AND LARDNER LLP;SUITE 500, 3000 K STREET NW, WASHINGTON, DC, 20007, US

(73) Assignees: KABUSHIKI KAISHA MEIDENSHA; Yoshiomi KONDOH

(21) Appl. No.: 10/537,357

(22) PCT Filed: Dec. 4, 2003
(86) PCT No.: PCT/JP03/15502

§ 371 Date: Jun. 3, 2005

(30) Foreign Application Priority Data
Dec. 6, 2002 (JP) 2002-355922

(51) Int. Cl. H01L 35/32

(52) U.S. Cl. 136/201; 136/204

(57) ABSTRACT

A self-driven direct energy conversion system is to be provided which can suppress global warming using a heat generation apparatus that can obtain a circulating type and open system energy source utilizing exhaustless, reusable thermal energy with no pollution in the natural world. The system has a thermal energy transfer module which a Peltier effect device group is separated from a Seebeck effect device group at a given distance, an electric power generating module, and an electrolyzer module in which thermal energy transfer and electric energy conversion are conducted, and a water electrolyzer circuit artificially forms a chemical energy source of hydrogen gas and oxygen gas easily pressurized, compressed, accumulated, stored, and transferred. Thus, thermal energy, electric power, and chemical energy are utilized.

### BACKGROUND OF THE INVENTION

1. Field of the Invention

The present invention relates to an apparatus and its system, which conduct energy interconversion or thermal energy transfer in different forms, particularly to a thermoelectric apparatus, a direct energy conversion system, and an energy conversion system, which directly convert or transfer thermal energy existing in the natural world to electric energy and chemical energy.

2. Description of the Related Art

Since the invention is the invention that has been developed based on publicly known and publicly used techniques (the forms of energy use by thermoelectric transducers) without conducting related art search, the related art known by the applicant does not fall in the documented publicly known invention. Hereinafter, the forms of energy use publicly known and publicly used will be described.

In the recent forms of energy use, most of them irreversibly utilize fossil fuels, nuclear power, and hydroelectric power. Particularly, the consumption of fossil fuels is a factor that increases global warming and environmental destruction. With the consumption of photovoltaic power, wind power, or hydrogen gas as so-called clean energy, it is only recently that an effort to implementing a reduction in load against environments has been started, but it is far to replace fossil fuels and nuclear power.

A thermoelectric transducer using the Seebeck effect (hereinafter, it is called a Seebeck device) is known as a device that converts thermal energy existing in the natural world to a directly usable form such as electric power, and it is being studied and developed for alternative energy to the fossil fuels and nuclear power. The Seebeck device is configured in which two types of conductors (or semiconductors) having different Seebeck coefficients are contacted with each other, and the difference between the numbers of free electrons of both conductors causes electrons to move and generate a potential difference between the two conductors. Thermal energy is applied to the contact to make free electrons to move actively, which allows thermal energy to be converted to electric energy. It is called the thermoelectric effect.

### SUMMARY OF THE INVENTION

However, a direct power generator device like the Seebeck device as described above cannot obtain sufficient electric power, and has limitations for use as a small-scale energy source. Therefore, in reality, the form of applications has also limitations.

Generally, the Seebeck device as described above is a device that combines a heating module (the high temperature side) with a cooling module (the low temperature side). Moreover, a thermoelectric device utilizing the Peltier effect (hereinafter, it is called a Peltier device) is also a device that combines a heat absorbing module with a heat generating module. More specifically, in the Seebeck device, the heating module thermally, mutually interferes with the cooling module, and in the Peltier device, the heat absorbing module thermally, mutually interferes with the heat generating module. Thus, the Seebeck effect and the Peltier effect decay over time.

Therefore, when the Peltier device and the Seebeck device are used to construct large-scale energy conversion facilities, it is unrealistic because physical limitations are imposed on installation locations for the facilities. Furthermore, the energy use that utilizes the typical Peltier device and Seebeck device is one-way use. For example, there is no technical concept to configure a circulating form such that the energy once used is used again.

Future energy development has to intend not to cause global warming or environmental destruction and to intend reuse. This is a great problem essential for energy development in future.

The invention is to solve the problem, and to provide a thermoelectric apparatus, a direct energy conversion system, and an energy conversion system, which utilize (reuse) thermal energy in the natural world, the energy exhaustlessly existing in the natural world with no pollution, to obtain various forms of energy such as thermal energy, electric energy, and chemical energy.

A system that can obtain an energy source satisfying the purpose needs to have a thermally open system and a circulating type form. More specifically, the invention provides an electric circuit system which can conduct thermal energy transfer by a Peltier device between areas apart from a given distance, directly convert thermal energy to electrical potential energy by a Seebeck device, and utilize the electrolysis of electrolyte solutions and water to convert electrical potential energy to chemical potential energy to easily store, accumulate and transfer energy.

For example, the system can effectively use and reuse thermal energy in the natural world with no use of fossil fuels, convert the thermal energy to electric energy for use as electric power, convert it to chemical energy, and thus construct an open energy recycling system. Therefore, a direct energy conversion system can be provided which can reduce global warming and have little environment load accompanied by pollution.

### BRIEF DESCRIPTION OF THE DRAWINGS

The teachings of the invention can be readily understood by considering the following detailed description in conjunction with the accompanying drawings, in which:

FIG. 1 is a schematic diagram for describing the principle of the physical construction for the Peltier effect and the Seebeck effect by energy bands;

FIG. 2 is a schematic diagram for describing a pair of Peltier effect heat transfer circuit systems in a first embodiment which can be spaced at a given distance;

FIG. 3 is a diagram illustrating temperature change with respect to time variation in the Peltier effect;

FIG. 4 is a diagram illustrating temperature change with respect to time variation in the Peltier effect;

FIG. 5 is a diagram illustrating temperature change with respect to change in current;

FIG. 6 is a diagram illustrating temperature change with respect to change in current;

FIG. 7 is a schematic diagram for describing a pair of circuit systems in a second embodiment which can be spaced at a given distance and convert to electric energy from thermal energy by the Seebeck effect;

FIG. 8 is a schematic circuit diagram illustrating a self-driven heat transfer system that describes a direct energy conversion system using a thermoelectric apparatus in a third embodiment;

FIG. 9 is a diagram illustrating electromotive force with respect to change in temperature difference;

FIG. 10 is a schematic circuit diagram illustrating a self-driven heat transfer system that describes a direct energy conversion system using a thermoelectric apparatus in a fourth embodiment;

FIG. 11 is a schematic circuit diagram illustrating a self-driven heat transfer system that describes a direct energy conversion system using a thermoelectric apparatus in a fifth embodiment;

FIG. 12 is a schematic circuit diagram illustrating a self-driven heat transfer system that describes a direct energy conversion system using a thermoelectric apparatus in a sixth embodiment;

FIG. 13 is a schematic circuit diagram illustrating a self-driven heat transfer system that describes a direct energy conversion system using a thermoelectric apparatus in a seventh embodiment;

FIG. 14 is a schematic circuit diagram illustrating a self-driven heat transfer system that describes a direct energy conversion system using a thermoelectric apparatus in an eighth embodiment;

FIG. 15 is a schematic circuit diagram illustrating a self-driven heat transfer system that describes a direct energy conversion system using a thermoelectric apparatus in a ninth embodiment;

FIG. 16 is a schematic circuit diagram illustrating a self-driven heat transfer system that describes a direct energy conversion system using a thermoelectric apparatus in a tenth embodiment;

FIG. 17 is a schematic diagram illustrating a thermoelectric transducer apparatus and a direct energy conversion system in a first example; and

FIG. 18 is a schematic diagram illustrating a thermoelectric transducer apparatus and a direct energy conversion system in a second example.

### DESCRIPTION OF THE PREFERRED EMBODIMENT

Next, embodiments of the invention will be described.

As described in Summary of the invention, the Seebeck device (or the Peltier device) has a problem caused by the fact that the heating module is combined with the cooling module (or the heat absorbing module is combined with the heat generating module) into one device. Therefore, in order to solve this problem, the inventor focused attention on separating the heating module from the cooling module (the heat absorbing module from the heat generating module) of the Seebeck device (the Peltier device). Then, an experiment was conducted to confirm whether the heating module can be separated from the cooling module (the heat absorbing module can be separated from the heat generating module) as the device still has the characteristics, that is, the heating module and the cooling module (the heat absorbing module and the heat generating module) can be configured independently.

Hereinafter, a thermoelectric apparatus, a direct energy conversion system and an energy conversion system of embodiments according to the invention will be described in detail with reference to the drawings. In the embodiments, the entire direct energy conversion system utilizing natural energy is operated in an open system, and thus it is necessary to take notice that ‘the principle of increase of entropy which is held only in a closed system’ cannot be applied.

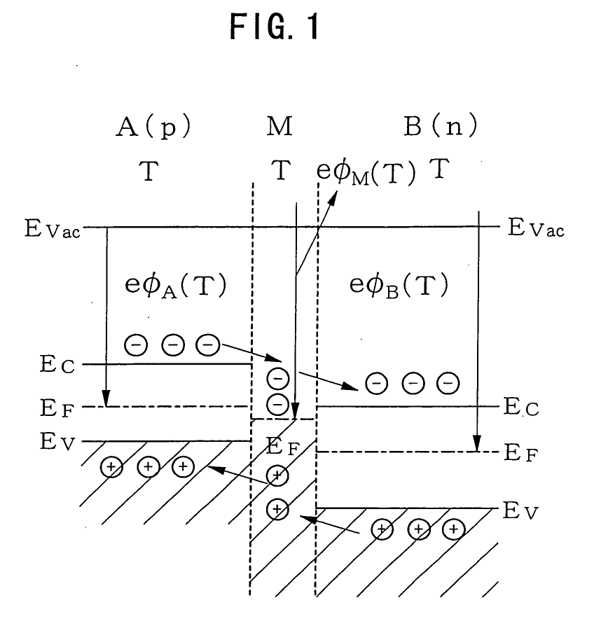

First, the basic technical concept (the principle) of the invention will be described. FIG. 1 is a schematic diagram for describing the principle of the physical mechanism of the Peltier effect and the Seebeck effect by energy bands. A schematic form is shown in which a joining member M having electrical conductivity such as metal is interposed between a conductive member A (for example, a p-type semiconductor in FIG. 1; hereinafter, it is called a first conductive member) and a conductive member B (for example, an n-type semiconductor in FIG. 1; hereinafter, it is called a second conductive member), both having different Seebeck coefficients, and an external electric field is applied from the second conductive member B in the direction of the first conductive member A. Furthermore, in FIG. 1, shaded areas depict a charged band with no free electrons, alternate long and short dash lines depict the Fermi level VF, a symbol EV denotes the upper end level of the charged band, a symbol EC denotes the lower end level of a conducting band, and a symbol EVac denotes the vacuum level.

As shown in FIG. 1, when an external electric field is applied from the second conductive member B in the direction of the first conductive member A, levels are arranged such that the Fermi level E_{F} of the joining member M having a finite thickness is arranged at the level below the Fermi level E_{F} of the first conductive member A (low level), and the Fermi level E_{F} of the second conductive member B is arranged below that level (low level). When no external electric field is applied, the Fermi levels E_{F} Of the conductive members A and B are the same level. Moreover, when an external electric field is applied from the first conductive member A in the direction of the second conductive member B, the Fermi levels E_{F} of the first conductive member A, the joining member M, and the second conductive member B are reversed in the level arrangement shown in FIG. 1.

Symbols φ_{A}(T), φ_{M}(T), and φ_{B}(T) in FIG. 1 denote the electrical potentials (barrier potentials) of the first conductive member A, the joining member M, and the second conductive member B, respectively, and are the potentials uniquely defined by the temperatures of the first conductive member A, the joining member M, and the second conductive member B regardless of the orientation of the external electric field. For example, when electrons having the electric charge e are to leap out of the first conductive member A, the joining member M, and the second conductive member B, they need energy of eφ_{A}(T), eφ_{M}(T), and eφ_{B}(T), respectively.

As described above, when no external electric field is applied, electrons are moved so that the Fermi level E_{F} of the first conductive member A, the Fermi level E_{F} of the joining member M, and the Fermi level E_{F} of the second conductive member A are the same level, the contact potential difference V_{BM} between the second conductive member B and the joining member M is ‘φ_{B}(T)−φ_{M}(T)’, and the contact potential difference V_{MA} between the joining member M and the first conductive member A is ‘φ_{M}(T)−φ_{A}(T)’.

In this state, when an external electric field is applied from the second conductive member B in the direction of the first conductive member A to carry current, the free electron flow in the conducting band and the electron flow in the charged band associated with the movement of holes go from the first conductive member A in the direction of the joining member M, and further from the joining member M in the direction of the second conductive member B. Moreover, since the drift velocity of free electrons by the external electric field is smaller than the thermal velocity of free electrons, it can be ignored.

Here, when attention is focused on an electron group of the free electron flow that goes from the first conductive member A in the direction of the joining member M and further from the joining member M to the second conductive member B, the total energy of the individual electrons in the marked electron group corresponds to a total sum of the electrical potential energy and the kinetic energy by the thermal velocity. The physical process that the marked electron group thus flows from the first conductive member A to the joining member M and from the joining member M to the second conductive member B is an electronically adiabatic process that external energy is not added to the marked electron group because each of the joint surface areas is small enough.

More specifically, when the marked electron group flows from the first conductive member A in the direction of the joining member M and from the joining member M to the second conductive member B side, the thermal energy of electrons is decreased by an increase in the electrical potential energy of electrons in each of the boundary surfaces (two boundary surfaces in FIG. 1), and the thermal velocity of the electrons flowed into each of the boundary surfaces is reduced.

The thermal velocity of the marked electron group reduced in each of the boundary surfaces causes thermal energy to be absorbed from free electron groups and conductive member atoms existed in the joining member M and the second conductive member B before at vary fast in equally distributed time, and thus a heat absorption phenomenon occurs near the boundary between the first conductive member A side of the joining member M and the joining member M side of the second conductive member B. The physical process like this is a physical mechanism that causes the heat absorption phenomenon by the Peltier effect. No heat absorption phenomenon described above occurs near the boundary between the joining member M side of the first conductive member A and the second conductive member B side of the joining member M.

Then, when an external electric field is reversed to inverse the direction of current (when the external electric field is applied from the first conductive member A in the direction of the second conductive member B), in reverse to FIG. 1, levels are arranged so that the Fermi level E_{F} of the joining member M having a finite thickness is arranged at the level above the Fermi level E_{F} of the first conductive member A (high level), and the Fermi level E_{F} of the second conductive member B is arranged at the level (high level) thereabove. Since the electrical potentials φ_{A}(T), φ_{M}(T), and φ_{B}(T) of the first conductive member A, the joining member M, and the second conductive member B are uniquely determined by the respective temperatures of the first conductive member A, the joining member M, and the second conductive member B, the magnitude relation is not varied and the direction of the electron flow is reversed.

Consequently, the kinetic energy in each of the boundary surfaces is increased by a reduction in the electrical potential energy of electrons, the thermal velocity of the electrons flowed into each of the boundary surfaces is increased, and thus a heat generation phenomenon occurs near each of the boundaries between the second conductive member B side of the joining member M and the joining member M side of the first conductive member A. Furthermore, no heat generation phenomenon occurs near the boundary between the joining member M side of the second conductive member B and the first conductive member A side of the joining member M.

In order to carry current, it is necessary to configure a closed circuit. In typical Peltier devices, a Peltier device circuit is configured to have a joining structure of ‘the conductive member A (T), the joining member M (T), and the conductive member B (T)’ in which the joining member M having a small absolute Seebeck coefficient is interposed between the first conductive member A and the second conductive member B and current is carried therethrough by an external power source. The greater the difference in the absolute Seebeck coefficient between the first conductive member A and the second conductive member B is in the Peltier device circuit thus configured, the greater the heat generation value or the heat absorption value becomes by the Peltier effect. The absolute Seebeck coefficient is a coefficient unique to the conductive member having temperature dependency.

In the Peltier device circuit where the closed circuit is thus configured, unless a great enough heat dissipation member (a member having a high heat dissipation effect) removes heat generation energy on the heat generation side, the conducting bands of the conductive member A (T), the joining member M (T), and the conductive member B (T) are to have equal, significantly high temperature, because these three members have excellent thermal conductivity as shown in FIG. 1, for example.

Consequently, a great amount of electrons in the charged band are thermally excited to the conducting bands, the Fermi level E_{F} is greatly increased to cause the electrical potentials of all the three conductors to be equal as ‘φ_{A}(T)=φ_{M}(T)=φ_{B}(T)’. When this state is made, the Peltier effect described in the principle is gone, and electric power externally added is consumed only for Joule heating the electrical resistance in three conducting bands. In order not to brought into this state, in general household electrical appliances and computers having a Peltier device circuit therein, a structure is adopted in which a great heat absorption body and heat dissipation material or an electrical fan are disposed on the heat generation side (near the heat generation side) of the Peltier device to suppress the dissipation of the Peltier effect.

On the contrary, in the invention, a coupling material (for example, two wiring materials) having excellent electrical characteristics (for example, thermal conductivity and electrical conductivity) is used to separate the heat generation side from the heat absorption side of the Peltier device circuit at a predetermined distance to form a thermally open system (for example, with the use of a coupling member (wiring material of long distance) that can secure a distance with no thermally mutual interference between the heat generation side and the heat absorption side), and the heat generation side and the heat absorption side are placed in thermally independent environments (different temperature environments) to prevent the Peltier effect from never being dissipated as well as the Peltier effect can be used.

In the Peltier device circuit thus configured, when the external electric field shown in FIG. 1 is not applied, the number of the free electrons in the conducting band and the number of holes in the charged band by thermal excitation are increased as the temperature T rises. Consequently, much more electrons are moved so that the Fermi level E_{F} on the first conductive member A side, the Fermi level E_{F} of the joining member M, and the Fermi level E_{F} on the second conductive member B side have the same level, and the contact potential difference V_{AM} (that is, ‘eφ_{A}(T)− eφ_{M}(T)’) between the first conductive member A and the joining member M becomes great.

In the case where two sets of the configurations shown in FIG. 1 without applying any electric field are serially connected, that is, in the case where ‘a unit formed of the first conductive member A (Tα) and the second conductive member B (Tα)’ is electrically, serially connected to ‘a unit formed of the first conductive member A (Tβ) and the second conductive member B (Tβ)’ with the coupling member (such as a wiring material), the serial potential difference voltage V becomes great as the temperature difference ‘Tα−Tβ’ is increased. The voltage V corresponds to output voltage by the Seebeck effect.

The invention is configured by joining two sets of units formed of two conductive members having different Seebeck coefficients with a coupling member, and the Peltier effect that carries current by the external electric field and the Seebeck effect that serially connects the contact potential differences without applying any external electric field have the similar physical basis. More specifically, the invention utilizes two features of the Peltier effect and the Seebeck effect having the similar physical mechanisms.

### First Embodiment

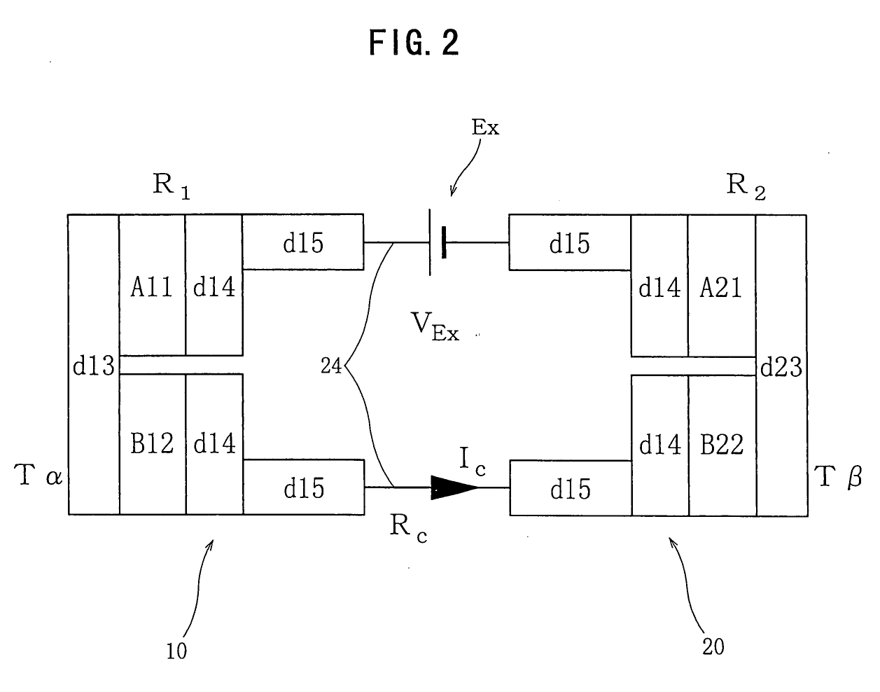

FIG. 2 relates to a thermoelectric apparatus of a first embodiment, and is a schematic circuit diagram for describing a pair of Peltier effect heat transfer circuit systems that can freely set a space between two thermoelectric transducers. In addition, in each of symbols shown in FIG. 2, R_{1 and R}₂ denote resistance of conductive members on the heat absorption side and the heat generation side (or on the high temperature side and the low temperature side), I_{C} denotes circuit current, R_{C} denotes circuit resistance at a connecting conductive member, and V_{EX} denotes external power source voltage. Each of the symbols is the same in embodiments and examples below.

As shown in FIG. 2, a first conductive member A11 and a second conductive member B12 having different Seebeck coefficients are joined to each other through a joining member d13 formed of a material of excellent thermal conductivity and electrical conductivity (such as copper, gold, platinum, and aluminum) to form a first thermoelectric transducer 10. Furthermore, as similar to the first thermoelectric transducer 10, a first conductive member A21 and a second conductive member B22 having different Seebeck coefficients are joined to each other through a joining member d23 to form a second thermoelectric transducer 20.

Moreover, the surfaces of the first conductive member A11 and the second conductive member B12 opposite to the joining member d13 is joined to the surfaces of the first conductive member A21 and the second conductive member B22 opposite to the joining member d23 with a coupling member of excellent thermal conductivity and electrical conductivity (a wiring material formed of copper, gold, platinum, and aluminum) 24. Then, a direct-current power supply Ex is serially connected to a part of the coupling member 24 (for example, the center part of one conductive member) to configure a pair of Peltier effect heat transfer electric circuit systems having the joining members 13 and 23 as a heat absorbing module and a heat generating module, respectively.

It is necessary that the coupling member 24 has length such that at least the first thermoelectric transducer 10 does not thermally, mutually interfere with the second thermoelectric transducer 20. Theoretically, the length can be set variously from a very short length about a few microns to a few hundreds kilometers.

The circuit system thus configured is a system that can separate the heat absorbing module (that is, a negative thermal energy source) from the heat generating module (that is, a positive thermal energy source) at a given distance to independently utilize the two positive and negative thermal energy sources.

In addition, in connecting between the thermoelectric transducers 10 and 20 with the coupling member 24, it is acceptable that the coupling members are directly connected to the individual conductive members except the portions where the joining members (d13 and d23) are contacted with the conductive members (A11, B12, B21, and B22) (hereinafter, it is called a joining member opposite part). Furthermore, for example, as shown in FIG. 2, it is acceptable that a conductive plate (such as copper, gold, platinum, and aluminum) d14 is connected to the joining member opposite part if necessary, and a terminal (such as copper, gold, platinum, and aluminum) d15 is further connected to the conductive plate d14.

Here, in the circuit configured as shown in FIG. 2, a demonstration experiment was done in which typical π type pn-junction devices (for example, CP-249-06L and CP2-8-31-08L made by Melcor, USA) were used as the thermoelectric transducers 10 and 20, the first thermoelectric transducer 10 was separated from the second thermoelectric transducer 20 at a distance (length of the coupling member 24 (copper line)) of 5 mm or 2 m, and current was fed to the circuit by an external direct-current power supply.

Consequently, a heat absorption phenomenon and a heat generation phenomenon by the Peltier effect occurred in the first thermoelectric transducer 10 and the second thermoelectric transducer 20 at the both ends of the circuit (that is, the joining members d13 and d23), and it was confirmed that the Peltier effect was not dissipated and was kept also in the configuration in which the first thermoelectric transducer 10 of the heat absorbing module was separated from the second thermoelectric transducer 20 of the heat generating module. Furthermore, when the direction of current fed was reversed, it was also confirmed that the heat absorption phenomenon and the heat generation phenomenon at the both ends were reversed.

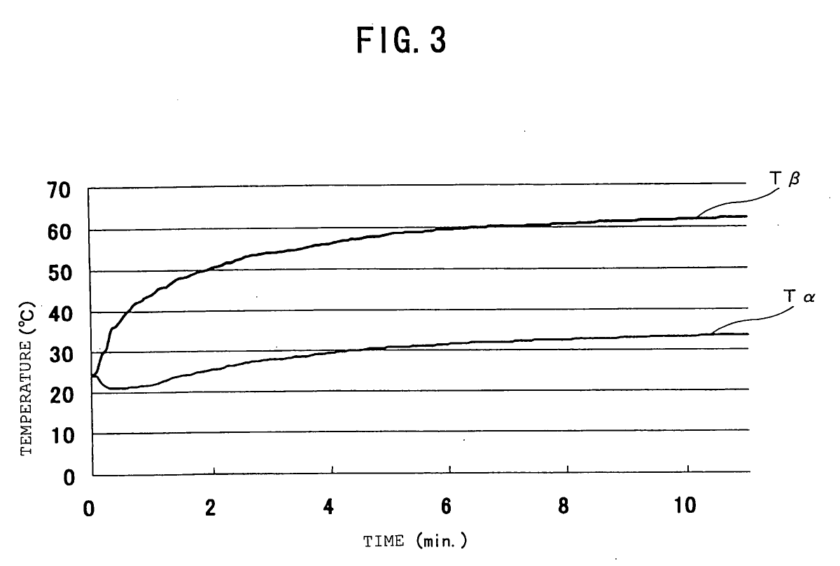

Subsequently, when the distance between the first thermoelectric transducer 10 and the second thermoelectric transducer 20 was apart at 5 mm in the circuit shown in FIG. 2, current was fed by the external direct-current power supply. As shown in FIG. 3, it is revealed that the temperature (temperature of the coupling member d23) Tβ of the heat generating module of the second thermoelectric transducer 20 was thermally conducted to the heat absorbing module side of the first thermoelectric transducer 10 to gradually increase the temperature (temperature of the coupling member d13) Tα of the heat absorbing module of the first thermoelectric transducer 10.

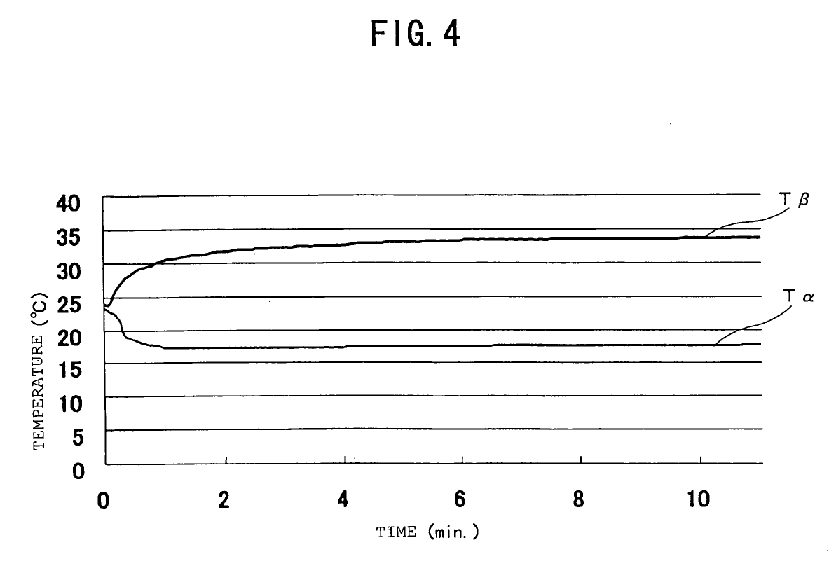

On the other hand, when the distance between the first thermoelectric transducer 10 and the second thermoelectric transducer 20 was apart at 2 m, as shown in FIG. 4, it is revealed that the heat of the heat generating module of the second thermoelectric transducer 20 was not heat transferred to the heat absorbing module side of the first thermoelectric transducer 10 and the first thermoelectric transducer 10 side did not thermally, mutually interfere with the second thermoelectric transducer 20 side. More specifically, it is revealed that it depended on external thermal energy drops.

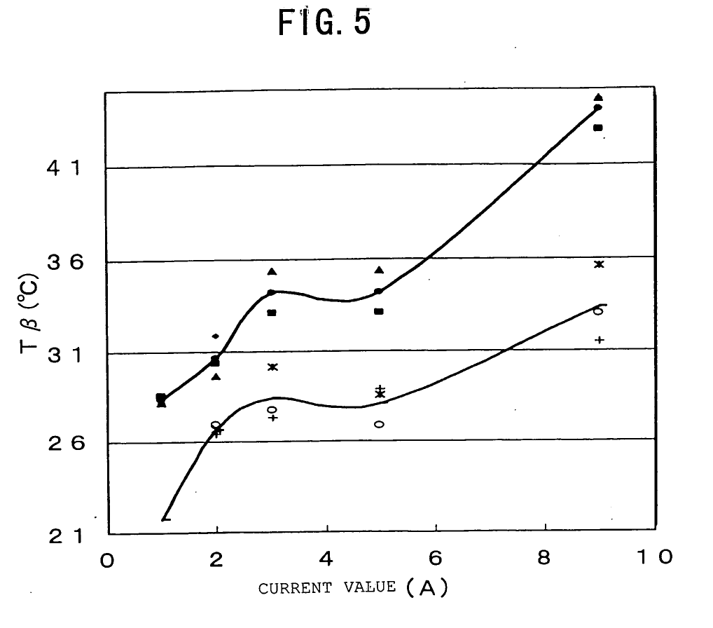

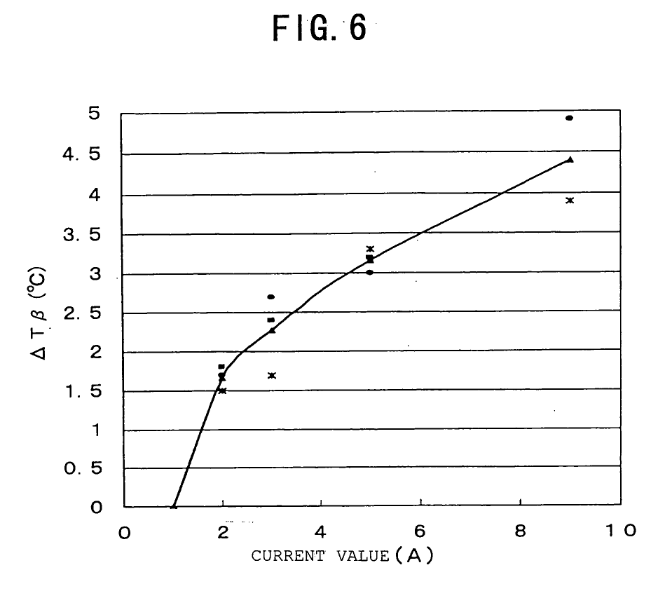

Then, data was obtained for three times each in the case where the heat absorbing module of the first thermoelectric transducer 10 was artificially heat controlled by the external heat source to keep a temperature of 10° C. (when heat controlled) and the case where artificial heat control was not done (before heated) in the state that the temperature Tα of the heat absorbing module of the first thermoelectric transducer 10 came to equilibrium with the temperature Tβ of the heat generating module of the second thermoelectric transducer 20 in the circuit shown in FIG. 2. The temperature change (° C.) and temperature variation (ΔTβ(° C.)) of the heat generating module of the second thermoelectric transducer 20 were measured with respect to the change in current of the external direct-current power supply, and the results were shown in FIGS. 5 and 6.

In addition, in FIG. 5, symbols ‘a solid diamond’, ‘a solid square’ and ‘a solid rectangle’ denote measurement values for the first, second and third times, respectively, when heat controlled; symbols ‘an asterisk’, ‘a follow circle’ and ‘plus’ denote the measurement values for the first, second and third times, respectively, before heated; and symbols ‘a solid circle’ and ‘minus’ denote a mean value of the measurement values before heated and when heat controlled, respectively. Furthermore, in FIG. 6, symbols ‘an asterisk’, ‘a solid circle’ and ‘a solid square’ denote the temperature difference between the cases when heat controlled and before heated for the first, second and third times, respectively, in FIG. 5; and a symbol ‘a solid rectangle’ denotes a mean value of the temperature differences in the cases when heat controlled and before heated.

The results shown in FIG. 5 reveal that the difference was made in the temperature on the heat generation side before heated and when heat controlled as the current of the external current power source was increased and the temperature difference was also increased. More specifically, it was revealed that thermal energy transfer was done in accordance with the thermal energy input from the first thermoelectric transducer 10 side. Moreover, as shown in FIG. 6, it was also revealed that the temperature variation ΔTβ was increased as the current of the external current power source was increased, and the amount of thermal energy transfer was also increased.

Therefore, it could be confirmed that the Peltier effect circuit shown in FIG. 2 has external thermal energy input dependency and current dependency for thermal energy transfer and the transfer amount is increased as the current is increased. More specifically, it can be said that the principle was demonstrated that thermal energy is transferred from the heat absorbing module side to the heat generating module side of the circuit (so-called heat pumping using the free electrons in the conductors) and thermal energy transfer is possible by the free electrons in the conductors. Furthermore, it could be confirmed that the amount of thermal energy transfer depends on current and the transfer amount is increased as the current is increased.

In addition, for the temperature dependency, securing at least the distance that maintains the relationship ‘the temperature Tα of the heat absorbing module<the temperature Tβ of the heat generating module’ can obtain the Peltier effect by the configuration different from the configuration shown in FIG. 2. However, preferably, the distance is secured that a thermoelectric transducer having heat absorption action (hereinafter, it is called a heat absorption device, corresponding to the first thermoelectric transducer 10 in FIG. 2) does not thermally, mutually interfere with a thermoelectric transducer having heat generation action (hereinafter, it is called a heat generation device, corresponding to the thermoelectric transducer 20 in FIG. 2). For example, in the coupling member 24 shown in FIG. 2, when a length is provided so that at least the first thermoelectric transducer 10 does not thermally, mutually interfere with the second thermoelectric transducer 20, theoretically, the length can be set variously from a very short length about a few microns to a few hundreds kilometers or longer.

### Second Embodiment

The external direct-current power supply E_{X} was removed from the Peltier effect circuit shown in FIG. 2 of the first embodiment, and the both ends of the circuit, that is, the joining member d13 of the first thermoelectric transducer 10 and the joining member d23 of the second thermoelectric transducer 20 were heated and cooled to provide a temperature difference about a temperature of 80° C. It could be confirmed that an electromotive force of 0.2 mv was generated at the terminal where the power source E_{X} had been removed. Furthermore, it could also be confirmed that the Seebeck effect was not dissipated and was kept in the configuration in which the first thermoelectric transducer 10 of the heating side was separated from the second thermoelectric transducer 20 of the cooling side.

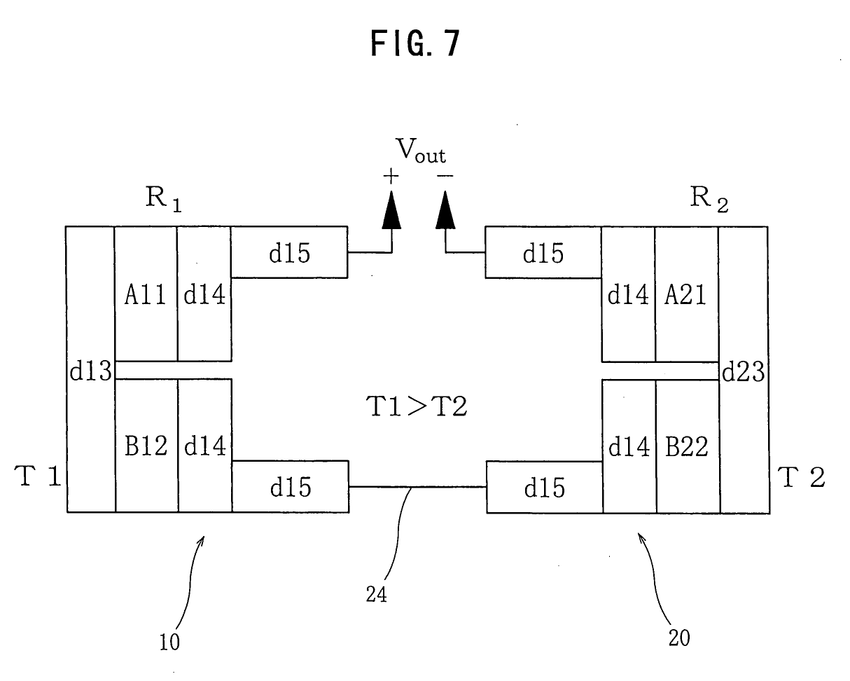

FIG. 7 relates to a second embodiment, and is a schematic circuit diagram for describing a pair of direct conversion circuit systems from thermal energy to electric energy by the Seebeck effect which can freely set the space between two thermoelectric transducers.

In the circuit system shown in FIG. 7, the direct-current power supply is removed from the circuit system as similar to that in FIG. 2, the length of a coupling member is adjusted so that at least a first thermoelectric transducer 10 does not thermally, mutually interfere with a second thermoelectric transducer 20 (for example, a length is adjusted from a very short length about a few microns to a few hundreds kilometers, if necessary), and a part of the coupling member 24 is cut to form an output voltage terminal.

In the circuit system shown in FIG. 7, a heat absorbing module (a joining member d13) of the first thermoelectric transducer 10 and a heat absorbing module (a joining member d23) of the second thermoelectric transducer 20 are placed in different temperature environments, and the temperature difference ‘T1−T2’ in environmental temperatures T1 and T2 is kept finitely. Thus, thermal energy existing in different environments can be directly converted to electrical potential energy by the Seebeck effect and can be used as an electric power source, for example.

Here, in the circuit system configured as shown in FIG. 7, typical π type pn-junction devices were used as the thermoelectric transducers 10 and 20, the first thermoelectric transducer 10 was apart from the second thermoelectric transducer 20 (length of the coupling member 24 (copper line)) at a distance of 2 m, a part of the coupling member 24 (for example, the center part of one coupling member) was cut, and the heat absorption module (the joining member d13 of the first thermoelectric transducer 10) and the heat generating module (the joining member d23 of the second thermoelectric transducer 20) at the both ends of the circuit system were externally heated and cooled while voltage output by the Seebeck effect was measured by a voltage measuring device at the cut part. Thus, positive and negative output voltages could be measured. Moreover, when the heat generating module was heated and the heat absorption module was cooled, it could be confirmed that the positive and negative of output voltages were reversed.

Furthermore, since the Seebeck effect directly converts temperature difference to electrical potential energy, for example, in the configuration shown in FIG. 7, the distance that at least maintains the relationship ‘T1>T2’ is secured to obtain the effect. However, preferably, a distance is secured that at least the first thermoelectric transducer 10 does not thermally, mutually interfere with the second thermoelectric transducer 20. For example, in the coupling member 24, when a length is provided so that at least the first thermoelectric transducer 10 does not thermally, mutually interfere with the second thermoelectric transducer 20, theoretically, the length can be set variously from a very short length about a few microns to a few hundreds kilometers or longer.

As the first and second embodiments described above, the idea has never been considered before that the conductive members configuring the Peltier device and the Seebeck device are separated at a given distance with the coupling member having excellent thermal conductivity. The thermal energy transfer in the configuration like this has a physical mechanism as the principle in which the electronically thermal insulation phenomenon described in detail above and the current carried through the coupling member of excellent thermal conductivity at the rate of electromagnetic waves allow instantaneous transfer even though the heat absorbing module side is apart from the heat generating module side of the circuit system at a long distance.

The transfer mechanism of thermal energy is assumed that an electron group electromagnetically pushes its adjacent electron group and this slight move propagates through electron groups in the conductor at the rate of electromagnetic waves to transfer thermal energy, not the free electron group in the conductor (for example, the coupling member) itself carrying thermal energy. Physically, heat generation and heat absorption occur independently at any places in the circuit system, but heat absorption energy and heat generation energy in the heat absorbing module and the heat generating module where the same amount of the current I is carried consequently become the same amount (nearly the same amount) by the current continuity principle of the electric circuit system configured, and the energy conservation law is held.

### Third Embodiment

In a third embodiment, based on the basic technical concept of the invention, specific configurations for achieving an object of the invention (for example, specific examples of the configurations shown in the first and second embodiments) will be described.

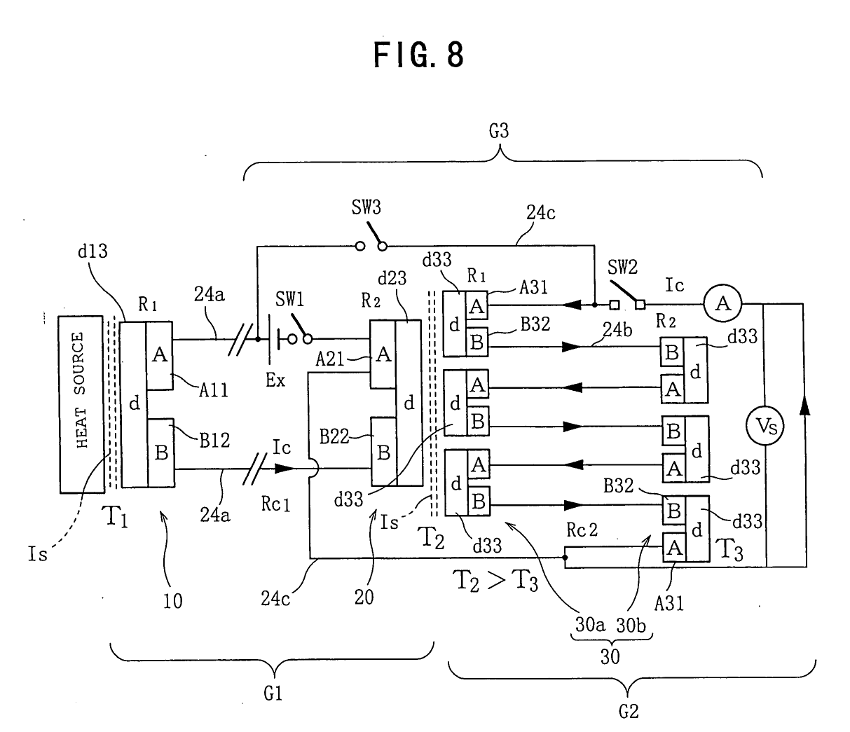

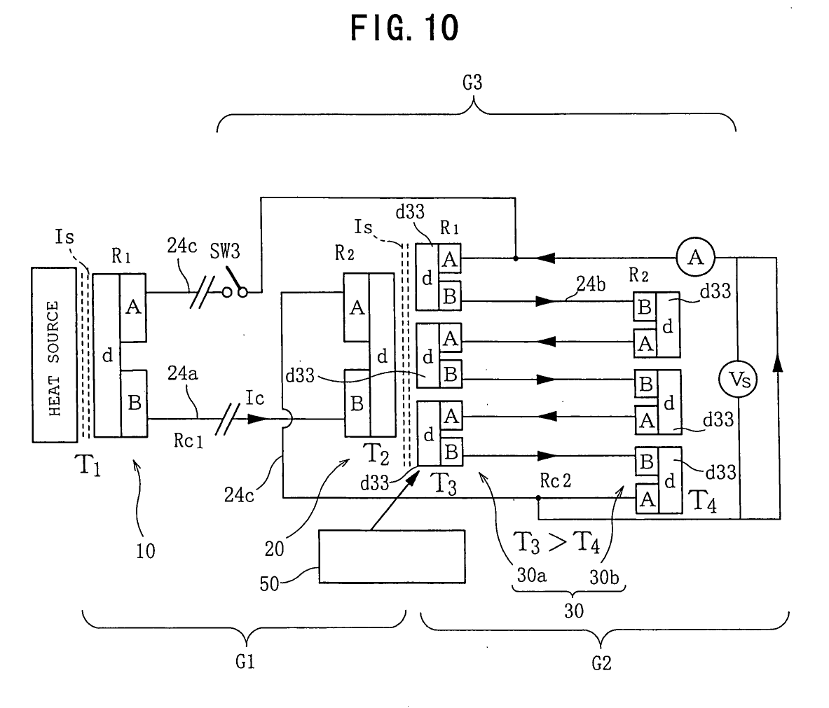

FIG. 8 is a schematic circuit diagram illustrating a self-driven heat transfer system for describing a direct energy conversion system using a thermoelectric apparatus (for example, the thermoelectric apparatus of the first embodiment) in the third embodiment. In addition, in FIG. 8 (and FIGS. 10 to 16 described later), Vs denotes voltage output, R_{C1} and R_{C2} denote circuit resistance, and I_{C} denotes circuit current. Furthermore, a symbol 30 denotes a thermoelectric transducer as similar to the first thermoelectric transducer 10 and the second thermoelectric transducer 20 shown in FIG. 7. Moreover, Is denotes an insulating material having excellent thermal conductivity and insulation properties (for example, silicone oil, surface anodized metal, and an insulating sheet). Besides, conductive plates and terminals disposed on the joining member opposite parts of each of the thermoelectric transducers are the same as those in the first and second embodiments, and thus they are not shown in the drawing. This system is operated in the configuration and by the operating procedures (1) to (3) below.

(1) First, as similar to the first and second embodiments, a first thermoelectric transducer 10 and a second thermoelectric transducer 20 are placed in different temperature environments (T1 and T2) apart from a predetermined distance, and each of joining member opposite parts of a first conductive member A11 and a second conductive member B12 of the thermoelectric transducer 10 is joined to each of joining member opposite parts of a first conductive member A21 and a second conductive member B22 of the thermoelectric transducer 20 with a coupling member of excellent thermal conductivity (wiring material formed of copper, gold, platinum, and aluminum) 24a. Then, an external direct-current power supply Ex and a switch SW1 are connected to a part of the coupling member 24a to configure a thermal energy transfer module G1 formed of a pair of Peltier effect heat transfer electric circuit systems that the joining members d13 and d23 shown in FIG. 2 are formed into the heat absorbing module and the heat generating module, respectively.

It is necessary to provide a length to the coupling member 24a so that at least the first thermoelectric transducer 10 does not thermally, mutually interfere with the second thermoelectric transducer 20. Theoretically, the length can be set variously from a very short length about a few microns to a few hundreds kilometers or longer.

The switch SW1 of the thermal energy transfer module G1 is turned on to drive the external direct-current power supply Eₓ. Thus, thermal energy is transferred from the heat source side (the heat source side of the temperature T1) in the direction of an electric power generating module G2 (an electric power generating module G2 formed of 2 m of thermoelectric transducers 30, described later, (m is a natural number; two transducers are used in FIG. 8)) at a given distance between the Peltier effect circuit systems of the thermal energy transfer module G1. Moreover, in FIG. 8, an insulating material Is is interposed between the heat source and the thermal energy transfer module G1.

(2) The electric power generating module G2 using the Seebeck effect is disposed on the heat generation side of the thermal energy transfer module G1 through the insulating material Is. For the electric power generating module G2, in order to increase output voltage by the Seebeck effect, 2n of thermoelectric transducers 30 formed of a first conductive member A31 and a second conductive member B32 having different Seebeck coefficients joined with a joining member d33 are used (n is a natural number; six transducers are used in FIG. 8), each of the thermoelectric transducers 30 is serially connected in multistage with a coupling member 24b. A heat absorption device 30a in each of the thermoelectric transducers 30 is disposed on the high temperature side (three devices are disposed in FIG. 8), and a heat generation device 30b is disposed on the low temperature side (three devices are disposed in FIG. 8) for configuration. A switch SW2 is connected to a part of the coupling member 24b.

The switch SW2 is turned on to heat the environmental temperature of the heat absorbing module of the heat absorption device 30a (the joining member d33 of the heat absorption device 30a) in the electric power generating module G2 to the temperature T2 by the thermal energy transferred through the insulating material Is, and the environmental temperature of the heat generating module of the heat generation device 30b (the joining member d33 of the heat generation device 30b) to the temperature T3 or the environmental temperature is air-cooled or water-cooled, if necessary to the temperature T3. The state ‘T2>T3’ is maintained to generate electrical potential energy in the electric power generating module G2. Furthermore, as shown in FIG. 8, when 2n of the thermoelectric transducers are used in the electric power generating module G2, the electric power generating module G2 has n of the Peltier effect circuits. The thermal energy on the heat generation side (the joining member d23) in the thermal energy transfer module G1 is absorbed into the heat absorption side (the joining member d33 of the heat absorption device 30a) in the electric power generating module G2 through the insulating material Is, and further transferred to the heat generation side (the joining member d33 of the heat absorption device 30b) in the electric power generating module G2.

(3) An electric power feedback module G3 is configured in which the thermal energy transfer module G1 (a part of the coupling member 24a) is connected to the electric power generating module G2 (a part of the coupling member 24b) with a coupling member 24c so that the output voltage (electrical potential energy) generated in the electric power generating module G2 is positively fed back to the thermal energy transfer module G1. A switch SW3 is connected to a part of the coupling member 24c.

Then, the switch SW2 and the switch SW3 are turned on, and the switch SW1 is turned off to cut off the external direct-current power supply. Thus, the output voltage generated in the electric power generating module G2 is positively fed back to the thermal energy transfer module G1 by the electric power feedback module G3, current is kept carried through the circuit system using the Peltier effect in the thermal energy transfer module G1, and thermal energy transfer by the thermal energy transfer module G1 is also maintained. More specifically, the circuit system is to be kept driven as long as the thermal energy of the heat source is finally used as the thermal energy of the heat source in the module G1.

Moreover, the circuit system shown in FIG. 8 is thermodynamically a system operated in an open system. It should be noted that ‘the principle of increase of entropy which is held only in an independently closed system’ cannot be applied to this system and the circuit system is never a scientifically unfeasible system like a perpetual motion machine.

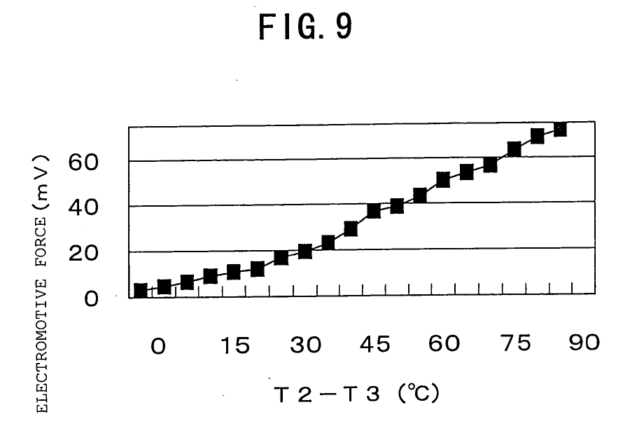

Furthermore, in order to check the Seebeck effect in the electric power generating module G2 of the circuit shown in FIG. 8, electromotive force was measured with respect to the temperature difference ‘T2−T3’ between T2 and T3. It could be confirmed that the electromotive force obtained becomes greater as ‘T2−T3’ is increased as shown in FIG. 9. More specifically, according to the circuit shown in FIG. 8, it could be confirmed that the temperature difference between T2 and T3 is kept to efficiently generate and maintain the electromotive force by the Seebeck effect. This experimental result shown in FIG. 9 can also be obtained by using the circuit shown in FIG. 7.

### Fourth Embodiment

FIG. 10 is a schematic circuit diagram illustrating a self-driven heat transfer system that describes a direct energy conversion system using a thermoelectric apparatus in a fourth embodiment, and is a schematic circuit diagram illustrating a self-driven heat transfer system that further improves the circuit system shown in FIG. 8. This improved system is operated in the configuration and by the operating procedures (1) to (4) below. In addition, the same symbols are used for the same symbols as those shown in FIG. 8, omitting the detailed description.

(1) In the circuit system shown in FIG. 8, the switch SW1 and the external direct-current power supply Ex connected between the thermoelectric transducers 10 and 20 are removed, and the coupling member 24c having the switch SW3 is connected to the conductive member A11 of the thermoelectric transducer 10 to configure the electric power feedback module G3. In an electric power generating module G2 shown in FIG. 10, the temperature on the high temperature side of the Seebeck circuit system (a joining member d33 of a heat absorption device 30a in FIG. 10) to T3 by firing lumber or by an auxiliary heater 50 such as a small-sized heater, if necessary. The low temperature side (a joining member d33 of a heat absorption device 30b in FIG. 10) of the electric power generating module G2 is set to the environmental temperature, or the environmental temperature is air-cooled or water-cooled (externally cooled by a cooling device) to the temperature T4, and the state ‘T3>T4’ is kept to provide Seebeck electromotive voltage enough to electrically drive the Peltier effect heat transfer module. More specifically, when the direct energy conversion system is start to use (initial stage), one or more of the heat absorption devices is externally heated or one or more of the heat generation devices is externally cooled in the electric power generating module G2. The environmental temperature difference is generated between the heat absorption device side and the heat generation device side to allow the Seebeck circuit system to obtain the Seebeck effect (a startup module (a plurality of startup modules) in an aspect of the invention is configured).

(2) A switch SW3 of the electric power feedback module G3 is turned on to positively fed back the output voltage generated in the electric power generating module G2 by the Seebeck effect to the Peltier effect heat transfer system in a thermal energy transfer module G1.

(3) The positive feedback in (1) allows carrying current through the Peltier effect heat transfer circuit in the thermal energy transfer module G1 for thermal energy transfer, and the thermal energy increases the temperature T2 (the joining member of the second thermoelectric transducer 20 in the thermal energy transfer module G1 increases its temperature to the temperature T2 in FIG. 8). Subsequently, T2 and T3 have nearly the same temperature, and then external heating by the auxiliary heater 50 is turned off.

(4) In the circuit system shown in FIG. 10, the energy initially introduced is added locally (to the joining member d33 of the heat absorption device 30a in FIG. 10), and thus energy can be suppressed smaller than the energy initially consumed as Joule heat loss in the Peltier effect thermal energy transfer circuit by the circuit system as shown in FIG. 8, for example. Particularly, it exerts a significant advantage in the case of a large-scale system in the thermal energy transfer distance between the thermal energy transfer circuits by the Peltier effect apart from a few tens kilometers to a few hundreds kilometers or longer.

### Fifth Embodiment

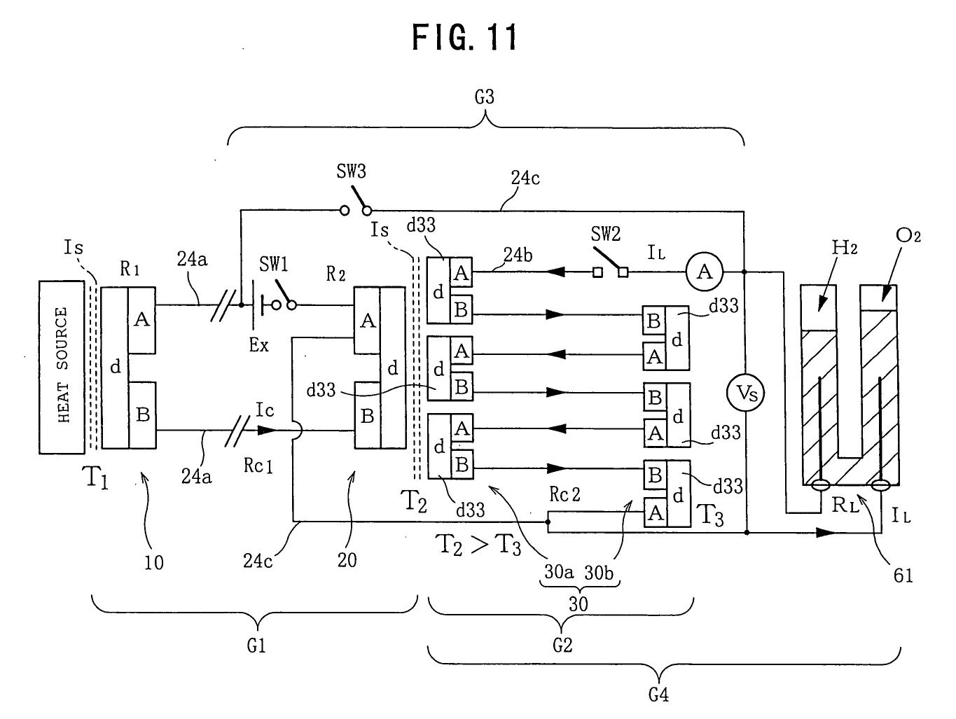

FIG. 11 is a schematic circuit diagram illustrating a self-driven heat transfer system that describes a direct energy conversion system using a thermoelectric apparatus in a fifth embodiment, and is a schematic circuit diagram illustrating a self-driven heat transfer system that further improves the external direct-current power supply as similar to that in FIG. 8.

More specifically, in the circuit system using an external direct-current power supply Ex as shown in FIG. 8, an electrolyzer module G4 is configured in which a plurality of thermoelectric transducers 30 are serially connected in multistage to form an electric power generating module G2 by the Seebeck effect, a load circuit 61 is disposed on the output terminal of output voltage of the module G2 in parallel with a positive feedback circuit module (that is, an electric power feedback module G3). For a specific example of the load circuit 61, for example, an electrolyzer is named which converts from electrical potential energy to chemical potential energy of hydrogen gas (H₂) and oxygen gas (O₂) by water electrolysis.

In addition, in symbols in the drawing, I_{L} denotes load current, and R_{L} denotes load resistance, which are the same in embodiments and examples described later. Furthermore, for the electrolyzer used as the load circuit 61, those generally commercially available can be used. Moreover, the configurations of a thermal energy transfer module G1 and the electric power generating module G2 are the same as those in FIG. 8, omitting the detailed description.

In the fifth embodiment, the electrical potential energy generated in the electric power generating module G2 can be converted to chemical potential energy of hydrogen gas (H₂) and oxygen gas (O₂) for use by the electrolyzer for electrolyzing water disposed in the electrolyzer module G4, for example. Moreover, the conversion of electrical potential energy to chemical potential energy allows securing energy easily pressurized, compressed, stored, accumulated and transferred.

Besides, chemical potential energy is positively fed back to the thermal energy transfer module G1 and the electric power generating module G2 through the electric power feedback module G3, and thus current is kept carried to the circuit systems using the Peltier effect and the Seebeck effect in the thermal energy transfer module G1 and the electric power generating module G2 as well as thermal energy transfer by the thermal energy transfer module G1 and electric power generation by the electric power generating module G2 can be maintained.

### Sixth Embodiment

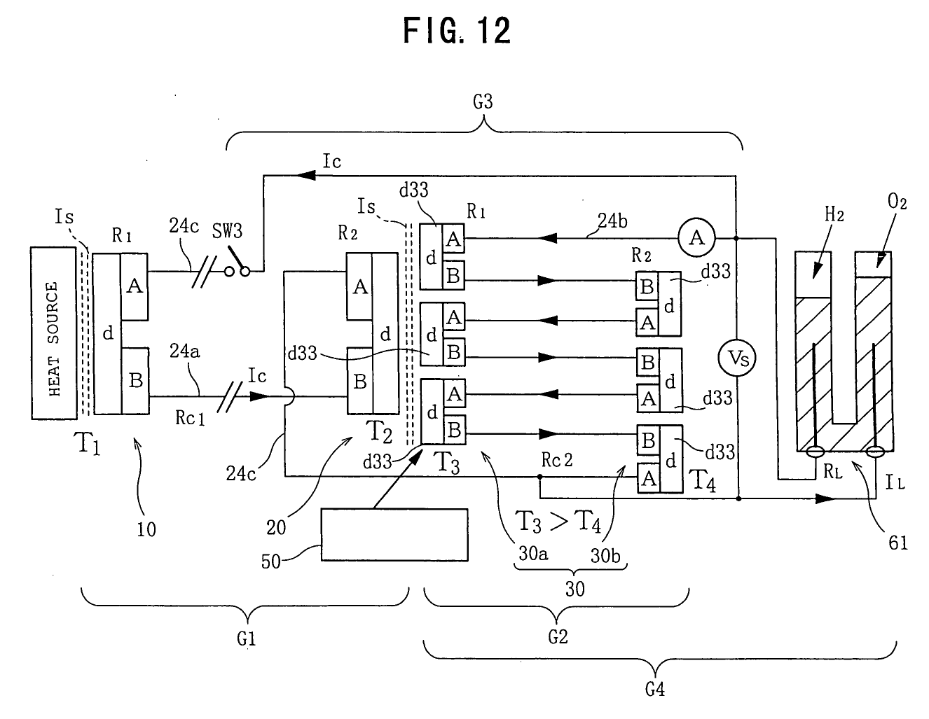

FIG. 12 is a schematic circuit diagram illustrating a self-driven heat transfer system that describes a direct energy conversion system using a thermoelectric apparatus in a sixth embodiment. For a specific example of a load circuit, an electrolyzer module G4 which electrolyzes water is disposed in the self-driven heat transfer system that improves the systems shown in FIGS. 10 and 11.

In the circuit system shown in FIG. 12, the electrolyzer module G4 which utilizes chemical potential energy is disposed on the system described in FIG. 10. More specifically, it is a self-driven heat transfer system effective in utilizing transferred thermal energy, electric power, and chemical potential energy by electrolysis of electrolyte solutions and water.

When the improved self-driven heat transfer system shown in FIG. 12 is installed in Japan as well as in regions and local areas all over the world, for example, it is apparent that the energy obtained by the system stimulates economy and food production in the regions and local areas, and at the same time, it can practically implement decreasing global warming and suppressing environmental destruction, which is significantly useful for sustaining humans swelled up to about 2.1 billion people and other creatures, for example.

### Seventh Embodiment

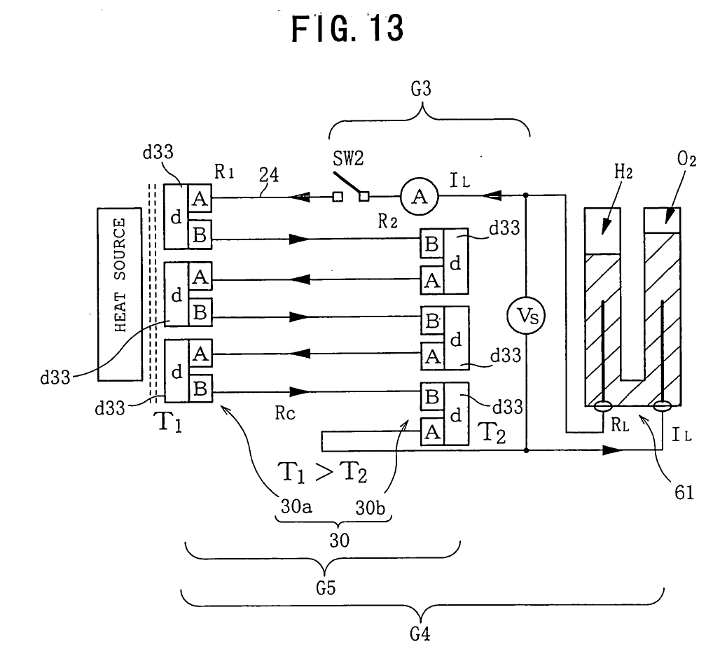

FIG. 13 is a schematic circuit diagram illustrating a self-driven heat transfer system that describes a direct energy conversion system using a thermoelectric apparatus in a seventh embodiment. This system does not use the Peltier effect thermal energy transfer circuit, and thermal energy from a heat source is directly converted to electrical potential energy by a direct thermal energy-electric power converting module G5 by the Seebeck effect which is a circuit configured to serially connect a plurality of thermoelectric transducers 30 in multistage. At the end of the output voltage, a water electrolyzer module G4 is placed as a specific example of a load circuit which converts to chemical potential energy by water electrolysis, for example.

As similar to the electric power generating module G2, the thermoelectric transducers 30 used for the direct thermal energy-electric power converting module G5 are serially connected in multistage by a coupling member 24, a heat absorption device 30a in each of the thermoelectric transducers 30 is disposed on the high temperature side (three devices are disposed in FIG. 8), and a heat generation device 30b is disposed on the low temperature side (three devices are disposed in FIG. 8).

According to the configuration of the seventh embodiment, the direct conversion circuit system that can drive by itself can obtain electrical potential energy and chemical potential energy from thermal energy.

### Eighth Embodiment

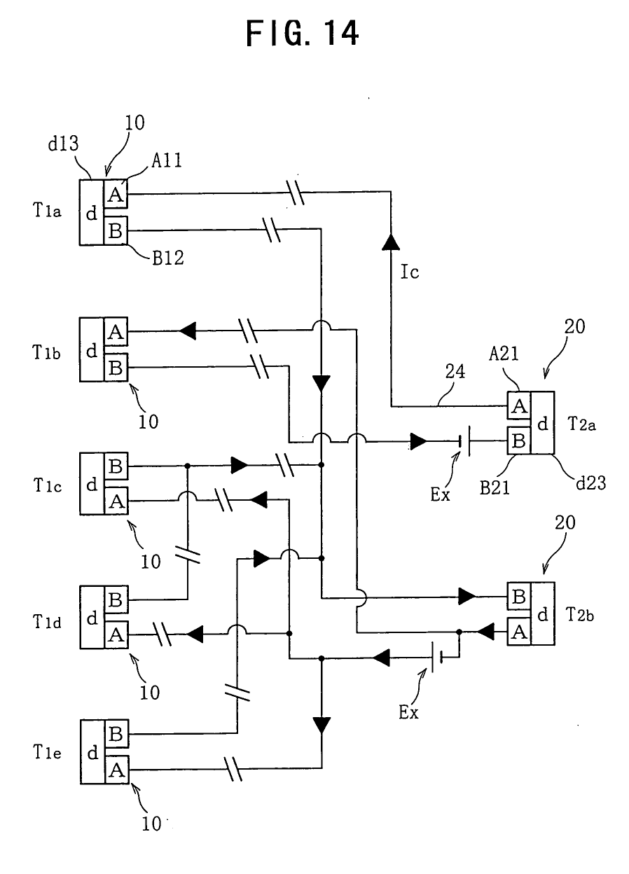

FIG. 14 is a schematic circuit diagram illustrating a self-driven heat transfer system that describes a direct energy conversion system using a thermoelectric apparatus in an eighth embodiment. This system further improves the circuit system shown in FIG. 2, and has a plurality of Peltier effect thermal energy transfer circuits (corresponding to the thermal energy transfer module G1).

First, a plurality of thermoelectric transducers 10 of the heat absorption device are placed in different temperature environments (five thermoelectric transducers 10 are placed in the environments at the temperatures T1a to T1e in FIG. 14) as well as a plurality of thermoelectric transducers 20 of the heat generation device are placed in different temperature environments (two thermoelectric transducers 20 are placed in the environments at the temperature T2a and T2b in FIG. 14). Furthermore, the environmental temperature for the thermoelectric transducer 10 is set higher than the environmental temperature for the thermoelectric transducer 20.

Then, a joining member opposite part of a first conductive member A11 and a second conductive member B12 in each of the thermoelectric transducers 10 is joined to a joining member opposite part of one or more of a first conductive member A21 and a second conductive member B22 in each of the thermoelectric transducers 20 with a coupling member 24. Furthermore, one part or more of each of the coupling members (two parts in FIG. 14) is connected to a direct-current power supply.

Accordingly, the circuit system that cannot lose the Peltier effect and can maintain it can be configured, and thermal energy can be transferred from a plurality of environments at different temperatures to another plurality of environments.

### Ninth Embodiment

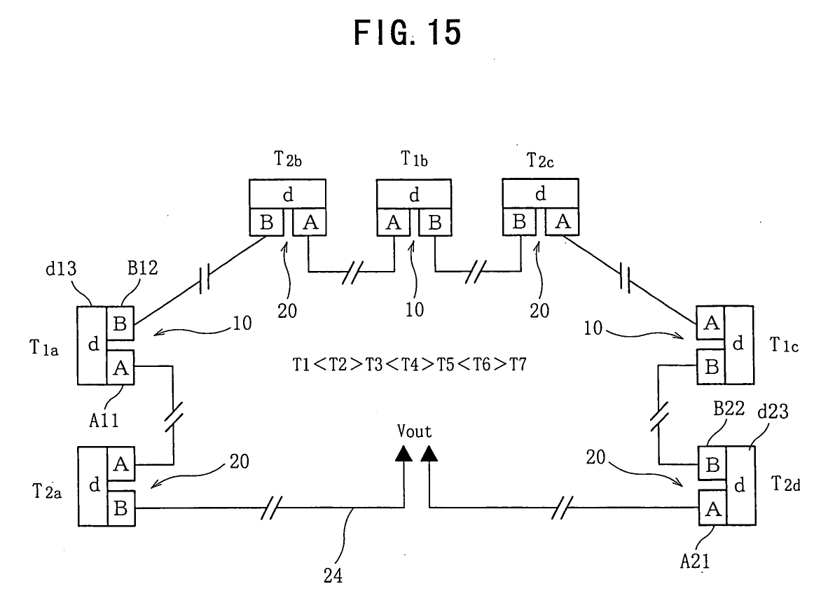

FIG. 15 is a schematic circuit diagram illustrating a self-driven heat transfer system that describes a direct energy conversion system using a thermoelectric apparatus in a ninth embodiment. This system further improves the circuit system shown in FIG. 7, and directly converts thermal energy existing in different environments to electrical potential energy by the Seebeck effect.

First, a plurality of thermoelectric transducers 10 of the heat absorption device are placed in different temperature environments (the temperatures T1a to T1c in FIG. 15) (three thermoelectric transducers 10 are placed in the environments at the temperatures T1a to T1c in FIG. 15), and a plurality of thermoelectric transducers 20 of the heat generation device are placed in different temperature environments (two thermoelectric transducers 20 are placed in the environments at the temperatures T2a and T2b in FIG. 14). In addition, the environmental temperature of the thermoelectric transducer 10 is set higher than the environmental temperature of the thermoelectric transducer 20 (in FIG. 15, for example, ‘T2a<T1a>T2b<T1b>T2c<T1c>T2d’).

Then, a joining member opposite part of a first conductive member A11 and a second conductive member B12 in each of thermoelectric transducers 10 is joined to a joining member opposite part of any one of a first conductive member A21 and a second conductive member B22 in each of thermoelectric transducers 20 with a coupling member 24, and thus the individual thermoelectric transducers 10 and 20 are serially connected. Moreover, a part of any one of the individual coupling members is cut to form into an output voltage terminal (a symbol V_{OUT}).

Accordingly, thermal energy existing in a plurality of environments at different temperatures can be directly converted to electrical potential energy by the Seebeck effect, and it can be utilized as an electric power source through the output voltage terminal.

### Tenth Embodiment

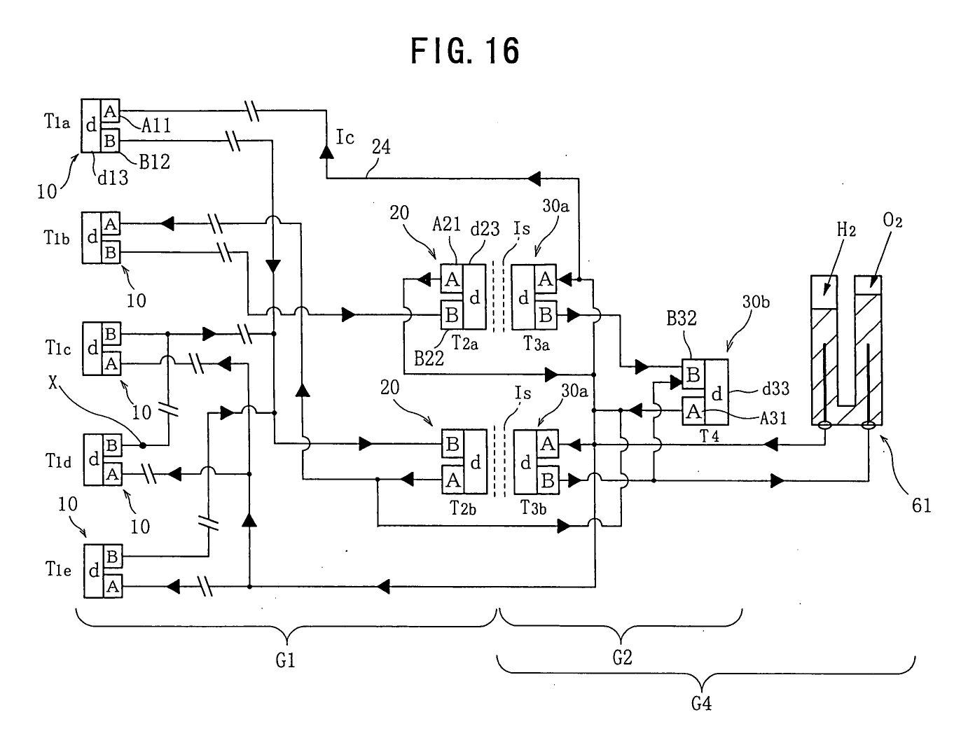

FIG. 16 is a schematic circuit diagram illustrating a self-driven heat transfer system that describes a direct energy conversion system using a thermoelectric apparatus in a tenth embodiment. This system further improves the circuit system shown in FIG. 12, utilizes thermal energy in a plurality of environments transferred by the Peltier effect thermal energy transfer circuit, and obtains electrical potential energy and chemical potential energy by the Seebeck effect.

First, to each of thermoelectric transducers 20 of a Peltier effect thermal energy transfer circuit formed of a plurality of thermoelectric transducers 10 and 20 (that is, corresponding to a thermal energy transfer module G1), a plurality of heat absorption devices 30a are disposed (a single heat absorption device is disposed to each of the thermoelectric transducers 20 (the temperatures T3a and T3b) in FIG. 16), and a plurality of heat generation devices are placed in an environment at a lower temperature (the temperature T4) than that of the environment for the heat absorption devices 30a (a single heat generation device is placed in FIG. 16).

Then, a joining member opposite part of a first conductive member A11 and a second conductive member B12 in each of the heat absorption devices 30a is joined to a joining member opposite part of one or more of a first conductive member A21 and a second conductive member B22 in each of heat generation devices 30b (a single joining member opposite part in FIG. 16) with a coupling member 24. Thus, an electric power generating module G2 by the Seebeck effect is configured. Furthermore, an electric power feedback module G3 (not shown in the drawing) is configured so that the output voltage of the electric power generating module G2 is positively fed back to the Peltier effect heat transfer system of the thermal energy transfer module G1. Moreover, a load circuit 61 is disposed in parallel with the electric power feedback module G3 with respect to an output terminal of output voltage of the electric power generating module G2, and thus an electrolyzer module G4 is configured.

Accordingly, electrical potential energy and chemical potential energy can be obtained from thermal energy transferred from a plurality of environments at different temperatures, and the electrical potential energy and chemical potential energy are positively fed back to the Peltier effect thermal energy transfer circuit to allow keeping the Peltier effect without loosing it.

In addition, the individual circuit systems of the configurations described in FIGS. 2, 7, 8, and 10 to 16 can separate the heat absorbing module from the heat generating module (or the heating module from the cooling module) at a predetermined distance apart, and thermal energy or electrical potential energy can be transferred from a short distance (for example, about a few microns) to a long distance (for example, a few hundreds kilometers). More specifically, a circulating type energy source acquiring system of no pollution can be constructed which can reuse exhaustless thermal energy in the natural world.

Furthermore, as shown in FIGS. 14 and 16, the direct energy conversion system is configured by connecting the coupling member so that a plurality of Peltier effect circuits are in parallel with each other (at least two Peltier effect circuits are in parallel with each other). Thus, for example, even when failure such as a break occurs in one place or more in the coupling member, (for example, a break occurs at a symbol X in FIG. 16), thermal energy transfer can be continuously conducted by a Peltier effect circuit (a Peltier effect circuit with no failure; for example, a Peltier effect circuit that transfers thermal energy in environments at the temperatures T1a to T1c, T1e in FIG. 16) disposed in parallel with that Peltier effect circuit where the failure occurs, and electrical potential energy can be obtained stably.

Moreover, for the conductive member forming the thermoelectric transducers shown in each embodiment, solid solutions are known as thermoelectric materials in low temperature areas (for example, room temperature) such as Bi₂Te₃, Bi₂Se₃, and Sb₂Te₃. For thermoelectric materials in high temperature areas exceeding at temperature 1000 K, Ce₃Te₄, La₃Te₄, and Nd₃Te₄ are known in addition to SiGe alloys. For thermoelectric materials in medium temperature areas, PbTe and AgSbTe—GeTe multi-compounds and Mg₂Ge—Mg₂Si are known. Preferably, a given conductive member is selected in consideration of temperatures in environments where a thermoelectric transducer is used.

Besides, the same material or different materials may be used for p-type and n-type conductive members that make a pair to configure a thermoelectric transducer. A given combination can be selected in accordance with temperatures in environments where a thermoelectric transducer is used.

Next, more specific examples will be described on the thermoelectric apparatus and the direct energy conversion system using the thermoelectric apparatus as the circulating type energy source acquiring system in the first to tenth embodiments.

### FIRST EXAMPLE

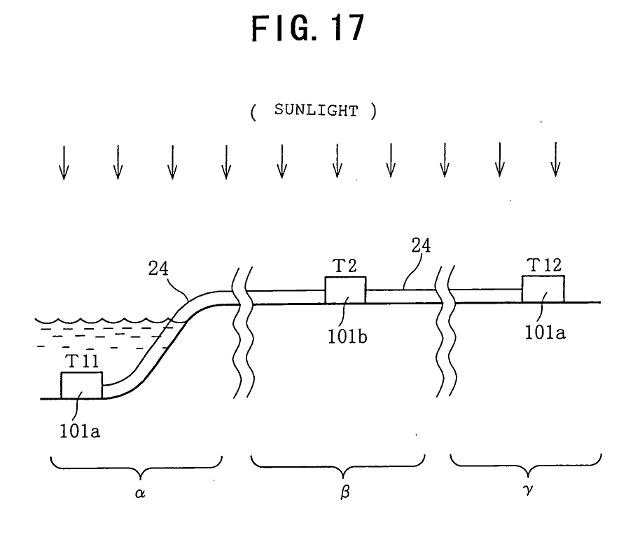

FIG. 17 is a diagram illustrating a first example according to the invention where the scale is great, and a specific example of a public energy supply infrastructure.

In FIG. 17, a symbol 101a denotes a thermoelectric transducer group on the heat absorption side (for example, corresponding to the individual first thermoelectric transducers 10 (particularly to the joining member d13 side of the first thermoelectric transducer 10) in FIG. 14) in the thermoelectric apparatus of the Peltier effect heat transfer circuit system (or a plurality of Peltier effect heat transfer circuit systems), and a symbol 101b denotes a thermoelectric transducer group on the heat generation side (for example, corresponding to the individual second thermoelectric transducers 20 (particularly to the joining member d23 side of the second thermoelectric transducer 20) in FIG. 14) disposed apart from the thermoelectric transducer group 101a on the heat absorption side at a predetermined distance. In addition, T11, T12, and T2 denote the temperatures of a region α (seawater and rivers), a region β, and a region γ, and T11 and T12 are set to temperatures higher than that of T2. The Peltier effect heat transfer circuit system thus configured is implemented as shown in (1) to (6) below.

(1) Since the seawater about 10 meters below water always flows at a stable temperature (a constant temperature), it is a stable thermal energy source throughout the year. The stable thermal energy in the seawater is transferred (long distant energy transfer) from the thermoelectric transducer group 101a on the heat absorption side to the thermoelectric transducer group 101b on the heat generation side by the Peltier effect heat transfer circuit system shown in FIG. 17.

A Seebeck effect device group (not shown in the drawing; corresponding to the individual heat absorption devices 30a in FIG. 16) is closely contacted with the thermoelectric transducer group 101b on the heat generation side, thermal energy transferred at a long distance is energy converted by the Seebeck effect to electrical potential energy (for example, as described in the second to fifth, seventh, ninth, and tenth embodiments, the Seebeck effect energy converts electrical potential energy), and thus stable electric power generation can be conducted throughout the year, for example. More specifically, infrastructure facilities such as power plants of no pollution utilizing natural energy (transferred thermal energy) can be constructed everywhere in Japan.

(2) Instead of placing the thermoelectric transducer group 101a on the heat absorption side in the seawater as (1), the thermoelectric transducer group 101a is placed in a river. The thermal energy in the river water is energy transferred at a medium distance to the thermoelectric transducer apparatus 101b on the heat generation side by the same means as (1) (the same means used for long distance energy transfer). The Seebeck effect device group is closely contacted with the thermoelectric transducer group 101b to energy convert from thermal energy to electrical potential energy. Thus, infrastructure facilities such as power plants of no pollution utilizing natural energy can be constructed everywhere in Japan as similar to (1).

(3) Instead of placing the thermoelectric transducer group 101a on the heat absorption side in the seawater and the river water as (1) and (2), the thermoelectric transducer group 101a is placed on a ground (the region γ in FIG. 17), and thermal energy is directly used from geothermal heat, thermal energy such as hot water waste, and sunlight. Thus, infrastructure facilities such as power plants of no pollution utilizing natural energy can also be constructed everywhere in Japan as similar to (1) and (2).

(4) The electric power obtained in the regions in (1) to (3) (electric power obtained by the infrastructure facilities such as power plants) is utilized for water electrolysis, based on the fifth to seventh, and tenth embodiments, for example, and thus electrical potential energy is energy converted to chemical potential energy of hydrogen gas and oxygen gas.

The hydrogen gas and oxygen gas accumulated by chemical potential energy are pressurized, compressed and stored in containers. Thus, transfer is facilitated, and the chemical potential energy source can be supplied and stored everywhere in Japan. The hydrogen and oxygen are again reacted with each other to convert to power energy and thrust energy and are used for hydrogen fuel cells, and thus energy can be utilized in accordance with purposes.

(5) Since wastes (products) generated in utilizing the chemical potential energy of hydrogen and oxygen of (4) is water, environment load as pollution is nearly zero.

(6) The energy sources from environments utilized in (1) to (5) are a part of that sunlight from the sun to the earth is converted to thermal energy, and are emitted outside the earth as radiant energy over time. The exemplary forms are ‘circulating type and sustainable energy utilization’ that uses a part of energy flows obtained from the sun.

### SECOND EXAMPLE

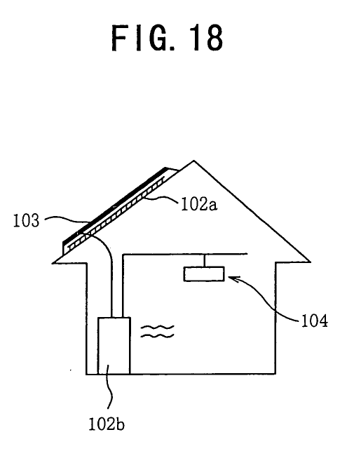

FIG. 18 is a diagram illustrating a second example according to the invention where the scale is medium, and a specific example of an energy supply system in a house, for example. In FIG. 18, a symbol 102a denotes a thermoelectric transducer group on the heat absorption side of thermoelectric apparatus in the Peltier effect heat transfer circuit system (or a plurality of Peltier effect heat transfer circuit systems), a symbol 102b denotes a thermoelectric transducer group on the heat generation side disposed apart from the thermal converter device group 102a on the heat absorption side at a predetermined distance, a symbol 103 denotes a material that easily absorbs sunlight (hereinafter, it is called a light absorbing material such as a black material), and a symbol 104 denotes an electrical appliance such as a lighting apparatus, which are implemented as shown in (1) to (4) below.

(1) Since a typical photovoltaic power generation device used for house roofs reflects almost all the sunlight energy, it cannot effectively utilize the energy. Then, the photovoltaic power generation device is placed over the house roof, the thin light absorbing material 103 is placed thereon as closely contacted with the both sides of the photovoltaic power generation device, and the thermoelectric transducer group 102a on the heat absorption side is placed with respect to the light absorbing material 103.

Accordingly, the light absorbing material 103 absorbs black energy to convert almost all the sunlight energy to thermal energy. Then, a Peltier effect heat transfer circuit system shown in FIG. 18 allows the thermoelectric transducer group 102a on the heat absorption side to absorb thermal energy obtained by the conversion, and the thermoelectric transducer group 101a transfers (middle and short distant energy transfer) it to the thermoelectric transducer group 101b on the heat generation side. The transferred thermal energy can be used as domestic space-heating appliances and heaters in accordance with purposes. In the example, essential points are in that the system does not need great external electric power, the energy obtained from the sunlight is converted to thermal energy in accordance with purposes, and the thermal energy can be utilized in various forms. When this new system is introduced along with photovoltaic power generation, the efficiency for converted energy utilization with respect to the incident solar energy is dramatically increased more than using only the photovoltaic power generation device.

(2) The example shown in FIG. 18 is thermal energy utilization in the daytime, and it is considered that outdoor temperatures are higher than indoor temperatures. However, for example, the temperature relationship sometimes reveres at night. Therefore, a switching device (not shown in the drawing) is configured in the energy supply system shown in FIG. 18, for example, the switching device is operated by a sensor (not shown in the drawing) which senses temperature change in outdoors and indoors or a person's will in the house, and the heat absorption side and the heat generation side in the energy supply system are switched. Thus, a desired thermal energy conversion (for example, indoor heat is exhausted to outside) can be conducted.

Accordingly, the orientation of current is inversed in the Peltier effect heat transfer circuit system shown in FIG. 18, the thermoelectric transducer groups 102a and 102b can be formed into the heat generation side and the heat absorption side of the Peltier effect heat transfer circuit system, for example, without replacing circuit modules (the heat absorption side and the heat generation side are switched in the Peltier effect heat transfer circuit system). Therefore, a cooler and an ice-making machine that need no large external electric power can be configured (when the improved Peltier effect heat transfer system according to the invention is used, for example, an air conditioner system may be configured with no external electric).

(3) A Seebeck effect device group (not shown in the drawing; corresponding to the individual heat absorption devices 30a in FIG. 16) is closely contacted with the thermoelectric transducer group 102a on the heat generation side where thermal energy is transferred (or 102b) as in (1) or (2), and then the transferred thermal energy is energy converted to electrical potential energy by the Seebeck effect (for example, as described in the second to fifth, seventh, ninth, and tenth embodiments, energy converted to electrical potential energy by the Seebeck effect). Thus, a medium-scale power generator, for example, can be constructed in the regions and homes.

(4) The medium-scale power generator in (3), for example, is utilized to conduct water electrolysis based on the fifth to seventh, and tenth embodiments, and then electrical potential energy can be energy converted to chemical potential energy of hydrogen gas and oxygen gas. Therefore, as similar to the first example, the system utilizing chemical energy in accordance with purposes can be installed in the regions and homes.

### THIRD EXAMPLE

For example, air around living environments always has some thermal energy unless it is at absolute zero Kelvin. The thermal energy held by the air around the living environments is utilized, that is, the description of small-scale examples is as follows.

(1) The thermoelectric transducer on the heat absorption side (or the transducer group) is placed apart from the thermoelectric transducer on the heat generation side (or the transducer group) at a required distance (a distance that the Peltier effect device group on the heat absorption side does not thermally, mutually interfere with the Peltier effect device group on the heat generation side) in the Peltier effect heat transfer circuit system (or a plurality of Peltier effect heat transfer circuit systems). Since the two transducer groups in the Peltier effect heat transfer circuit system can be used independently in accordance with the purpose for use, based on the first embodiment, for example, the cooling side is disposed in an indoor air conditioner and a refrigerator or a freezer and the heat generation side is disposed on a water heater, a pot, and a cooking heater. Thus, a cooler (cooling) and a heater can be used in a paired form at home without using large external electric power (also in this case, when the improved Peltier effect heat transfer system is used, various home appliances paired with cooling and heating can be used with no use of external electric power).

(2) Furthermore, the Peltier effect heat transfer circuit system is reduced in size to a portable form. Thus, for indoors, outdoors and camping areas, for example, various appliances paired with cooling and heating can be produced such as a small-sized refrigerator, pot, and cooking appliance.

(3) Specific examples of schemes for removing undesired heat in large-, medium-, and small-seized computers, personal computers, small-sized power sources, solids, liquids, and gases, and schemes for utilizing the removed heat are as follows.

For example, inside a typical computer, a central processing unit (CPU) device is a main heat generation source in the computer in operating. In order to remove the heat of the CPU device, currently a cooling thermal module is used that has a thickness of within about 1 cm using a Peltier effect device, the heat absorption side of the Peltier effect device is closely contacted with the CPU device, and a radiator plate and a small-sized fan for removing heat (small fan) are mounted on the heat generation side for forced heat exhaustion. Therefore, there are evitable problems of wasted electric power, airflow noise by the fan, and other noises.

On the other hand, when the invention is used, the space between the heat absorption side and the heat generation side in the Peltier effect heat transfer circuit system is separated from each other by the coupling member of excellent thermal conductivity at a few centimeters to a few meters, for example, in accordance with the computer size, the heat absorption side is closely contacted with the CPU device, and the heat generation side is mounted on a computer box of a large surface area and an external heat dissipation metal body or on a water heater. Thus, heat exhaustion with no noises and electric power savings can be intended at the same time.

Furthermore, in the invention, according to the circuit system that uses the improved Peltier effect heat transfer system and does not require external electric power, small-sized power sources and small-sized devices for removing undesired heat in solids, liquids, and gases can be commercialized, in addition to computers.

The following is the other exemplary applications of the invention. In the case of liquid, in an automatic vending machine that sells cold drinks and hot drinks, for example, the heat absorption side in a Peltier effect heat transfer circuit system is placed on the cold drink side, and the heat generation side in the Peltier effect heat transfer circuit system is placed on the hot drink side. Thus, such automatic vending machines using the improved Peltier effect heat transfer system can be developed that can dramatically reduce external electric power and that do not need external electric power.

Moreover, in the case of gas, heaters are paired in accordance with fish showcases and meat freezers, and thus circulating type devices can be implemented in a configuration combined with cooling, storage, heating and heat insulation with low energy and no pollution.

All the examples utilizing the improved Peltier effect heat transfer systems according to the invention are ‘the open energy recycling system that does not need fuels such as fossil fuels and external electric power and conducts thermal energy transfer based on thermal energy in the natural world and various types of energy conversion’, and can provide ‘the system that reduces global warming with less environment load accompanied by pollution’.

As described above, only the described specific examples are explained in detail in the invention. However, it is apparent for persons skilled in the art that various modifications and alterations can be done within the scope of the technical concept of the invention and such modifications and alterations of course belong to claims.

1. A thermoelectric apparatus comprising:
a Peltier effect heat transfer circuit system including:
a plurality of thermoelectric transducers, each of the thermoelectric transducers including a first conductive member and a second conductive member having different Seebeck coefficients, and a joining member joining the first conductive member and the second conductive member;
a coupling member connecting each of joining member opposite parts of the first conductive member and the second conductive member in each of at least one of the thermoelectric transducers electrically and serially to a respective one of joining member opposite parts of the first conductive member and the second conductive member in each of at least remaining one of the thermoelectric transducers; and
a direct-current power supply serially connected to at least one of the coupling members,
each of heat absorption modules in the Peltier effect heat transfer circuit system being disposed away from each of heat generating modules in the Peltier effect heat transfer circuit system so as to keep a temperature Tα of the heat absorbing module and a temperature Tβ of the heat generating module in a relationship of Tα<Tβ.

2. A direct energy conversion system comprising:
a directly energy conversion electric circuit system including:
a plurality of thermoelectric transducers, each of the thermoelectric transducers including a first conductive member and a second conductive member having different Seebeck coefficients, and a joining member joining the first conductive member and the second conductive member, and the thermoelectric transducers being placed in at least two different temperature environments; and
a coupling member connecting each of joining member opposite parts of the first conductive member and the second conductive member in each of at least one of the thermoelectric transducers electrically and serially to a respective one of joining member opposite parts of the first conductive member and the second conductive member in each of at least remaining one of the thermoelectric transducers,
each of the thermoelectric transducers placed in a high temperature environment being disposed away from each of the thermoelectric transducers placed in a low temperature environment, so as to keep a temperature T1 of the thermoelectric transducer placed in the high temperature environment and a temperature T2 of the thermoelectric transducer placed in the low temperature environment in a relationship of T1>T2,
the directly energy conversion electric circuit system being configured to allow to extract electrical potential energy from a given place in each of at least one of the coupling members to convert thermal energy to electrical potential energy.

3. An energy conversion system comprising:
a directly energy conversion electric circuit system including:
a plurality of thermoelectric transducers, each of the thermoelectric transducers including a first conductive member and a second conductive member having different Seebeck coefficients, and a joining member joining the first conductive member and the second conductive member, and the thermoelectric transducers being placed in at least two different temperature environments; and
a coupling member connecting each of joining member opposite parts of the first conductive member and the second conductive member in each of at least one of the thermoelectric transducers electrically and serially to a respective one of joining member opposite parts of the first conductive member and the second conductive member in each of at least remaining one of the thermoelectric transducers,
each of the thermoelectric transducers placed in a high temperature environment being disposed away from each of the thermoelectric transducers placed in a low temperature environment, so as to keep a temperature T1 of the thermoelectric transducer placed in the high temperature environment and a temperature T2 of the thermoelectric transducer placed in the low temperature environment in a relationship of T1>T2,
the directly energy conversion electric circuit system being configured to allow to extract electrical potential energy from a given place in each of at least one of the coupling members to convert thermal energy to electrical potential energy, and
the energy conversion system being configured to conduct electrolysis with the electrical potential energy extracted from a given place in each of at least one of the coupling members, to convert the electrical potential energy to chemical potential energy.

4. An energy conversion system comprising:
a thermoelectric apparatus including a Peltier effect heat transfer circuit system including:
a plurality of thermoelectric transducers, each of the thermoelectric transducers including a first conductive member and a second conductive member having different Seebeck coefficients, and a joining member joining the first conductive member and the second conductive member;
a coupling member connecting each of joining member opposite parts of the first conductive member and the second conductive member in each of at least one of the thermoelectric transducers electrically and serially to a respective one of joining member opposite parts of the first conductive member and the second conductive member in each of at least remaining one of the thermoelectric transducers; and
a direct-current power supply serially connected to at least one of the coupling members,
each of heat absorption modules in the Peltier effect heat transfer circuit system being disposed away from each of heat generating modules in the Peltier effect heat transfer circuit system so as to keep an environmental temperature T1 of the heat absorbing module and an environmental temperature T2 of the heat generating module in a relationship of T1>T2,
the energy conversion system being configured to supply thermal energy obtained from the thermoelectric transducer apparatus to each of the thermoelectric transducers placed in the high temperature environment in the direct energy conversion system according to claim 2 to obtain electrical potential energy, and
the energy conversion system being configured to positively feed back a part of the electrical potential energy to the thermoelectric apparatus for use as a direct-current power supply.

5. The direct energy conversion system according to claim 2, wherein the direct energy conversion system comprises at least one set of the directly energy conversion electric circuit systems, and a plurality of startup modules for applying a temperature difference by one of initial external heating and initial external cooling to at least one of the first conductive members and the second conductive members, and
wherein the direct energy conversion system is configured to directly convert to electrical potential energy from an environmental thermal energy source caused by the temperature differences in environments in a plurality of places separated from each other.

6. The energy conversion system according to claim 4, further comprising an on/off switch connected to each of at least one place in the coupling members, wherein the energy conversion system is configured to control positive feedback of the electrical potential energy by switching the on/off switch.

7. The thermal energy conversion system according to claim 6, wherein the thermal energy conversion system is configured to control positive feedback of the electrical potential energy by switching the on/off switch, and
wherein the thermal energy conversion system is configured to supply the electrical potential energy to the thermoelectric apparatus, and to cut off electric power supply from the direct-current power supply of the thermoelectric apparatus.

8. The thermal energy conversion system according to claim 4, wherein the thermal energy conversion system is configured to conduct electrolysis with the electrical potential energy to convert the electrical potential energy to chemical potential energy.

9. The direct energy conversion system according to claim 3, wherein the direct energy conversion system comprises at least one set of the directly energy conversion electric circuit systems, and a plurality of startup modules for applying a temperature difference by one of initial external heating and initial external cooling to at least one of the first conductive members and the second conductive members, and
wherein the direct energy conversion system is configured to directly convert to electrical potential energy from an environmental thermal energy source caused by the temperature differences in environments in a plurality of places separated from each other.

10. The direct energy conversion system according to claim 4, wherein the direct energy conversion system comprises at least one set of the directly energy conversion electric circuit systems, and a plurality of startup modules for applying a temperature difference by one of initial external heating and initial external cooling to at least one of the first conductive members and the second conductive members, and
wherein the direct energy conversion system is configured to directly convert to electrical potential energy from an environmental thermal energy source caused by the temperature differences in environments in a plurality of places separated from each other.

11. The energy conversion system according to claim 5, further comprising an on/off switch connected to each of at least one place in the coupling members, wherein the energy conversion system is configured to control positive feedback of the electrical potential energy by switching the on/off switch.

12. The thermal energy conversion system according to claim 11, wherein the thermal energy conversion system is configured to control positive feedback of the electrical potential energy by switching the on/off switch, and
wherein the thermal energy conversion system is configured to supply the electrical potential energy to the thermoelectric apparatus, and to cut off electric power supply from the direct-current power supply of the thermoelectric apparatus.

13. The thermal energy conversion system according to claim 5, wherein the thermal energy conversion system is configured to conduct electrolysis with the electrical potential energy to convert the electrical potential energy to chemical potential energy.

14. The thermal energy conversion system according to claim 6, wherein the thermal energy conversion system is configured to conduct electrolysis with the electrical potential energy to convert the electrical potential energy to chemical potential energy.

15. The thermal energy conversion system according to claim 7, wherein the thermal energy conversion system is configured to conduct electrolysis with the electrical potential energy to convert the electrical potential energy to chemical potential energy.
